(19) United States
(12) Patent Application Publication
(10) Pub. No.: US 2009/0279268 A1
(43) Pub. Date: Nov. 12, 2009

(54) Module

(76) Inventor: Kyung Joo Son, Ansan-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/296,437

(22) PCT Filed: Apr. 6, 2007
(86) PCT No.: PCT/KR2007/001690

§ 371 Date: Oct. 8, 2008

(30) Foreign Application Priority Data
Apr. 11, 2006 (KR) 10-2006-0032751

(51) Int. Cl. H05K 7/00; H05K 13/00

(52) U.S. Cl. 361/729; 29/592.1

(57) ABSTRACT

A module is provided. The module includes a first module unit provided at a top surface with a cavity and a second module unit on which one or more electronic devices are mounted. The second module unit is at least partly received in the cavity of the first module unit.

### TECHNICAL FIELD

Embodiemtns relates to a module.

### BACKGROUND ART

Recently, a variety of packages such as a ball grid array (BGA) and a system-in-package have been proposed to keep up with the developing demand for the miniaturization and high-integration of the semiconductor package system for realizing a module of an electronic appliance.

FIG. 1 is a view of a semiconductor package that is made by applying a package-on-package technology of the related art.

As shown in FIG. 1, an upper package 20 is stacked on a lower package 10, by which the upper package 20 is electrically physically connected to the lower package 20.

However, as the upper and lower packages 20 and 10 are stacked one another, an overall thickness increases. Therefore, this structure cannot be applied to an electronic appliance pursuing the miniaturization and high-integration.

### DISCLOSURE OF INVENTION

### Technical Problem

Embodiements provides a module that is suitable for the miniaturization and the high integration.

### Technical Solution

An embodiment provides a device including: a first module unit provided at a top surface with a cavity; and a second module unit on which one or more electronic devices are mounted, the second module unit being at least partly received in the cavity of the first module unit.

An embodiment provides a device including: a first module unit provided at a top surface with a cavity formed in a dual-step structure; and a second module unit on which one or more electronic devices are mounted to be received in the cavity of the first module unit.

### Advantageous Effects

According to the above embodiments, since the electronic device of the second module unit is received in the cavity of the first module unit, the miniaturization and high-integration can be realized.

Furthermore, since different electronic devices are respectively mounted on the first and/or second module units, the integration can be further enhanced.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of a module of the related art;

FIG. 2 is a sectional view of a first module unit applied to a module according to a first embodiment;

FIG. 3 is a sectional view of a second module unit applied to the module according to the first embodiment;

FIG. 4 is a sectional view illustrating a coupling state of the first and second module units of the module according to the first embodiment;

FIG. 5 is a sectional view of a first module unit applied to a module according to a second embodiment;

FIG. 6 is a sectional view illustrating a coupling state of first and second module units of the module according to the second embodiment; and

FIG. 7 is a sectional view illustrating a coupling state of first, second, and third module units of the module according to the second embodiment.

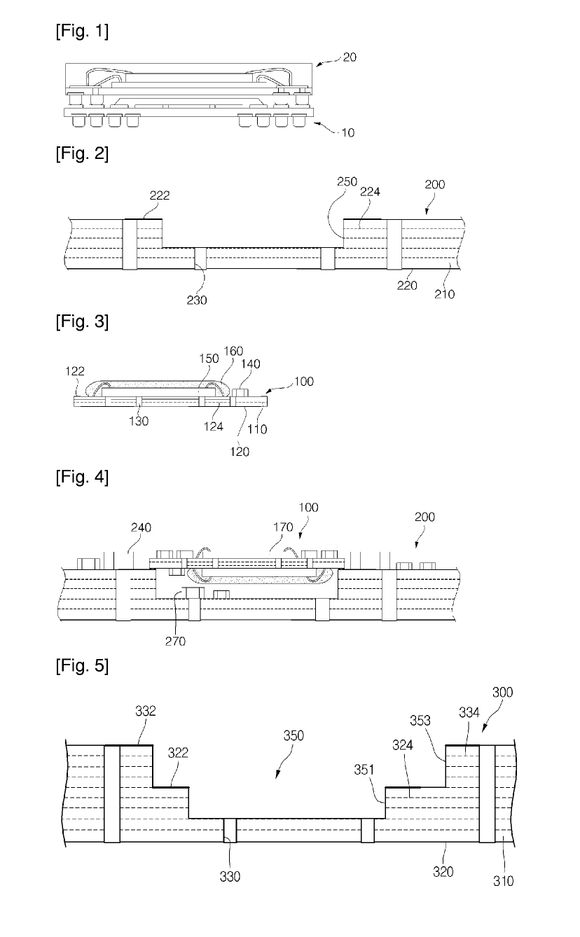

### BEST MODE FOR CARRYING OUT THE INVENTION

Reference will now be made in detail to the preferred embodiments of the present invention, examples of which are illustrated in the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art.

The following will described a module according to a first embodiment with reference to FIGS. 2 through 4.

In the description of the embodiments, when one element is said to be formed on or under another element, the first element may be formed directly above or under the second element so that the two elements are in contact, or the first element may be indirectly formed on the second element with a third element interposed between the first and second elements.

In the drawings, a thickness or size of each layer may be exaggerated or schematically illustrated for the descriptive convenience and clarity.

FIGS. 2 and 3 are sectional views that respectively illustrate first and second module units applied to a module of a first embodiment.

Referring to FIGS. 2 and 3, a module of the first embodiment includes a first module unit 200 and a second module unit 100 that is electrically physically coupled to the first module unit 200.

The first module unit 200 includes a substrate 210 and line patterns 220, 222, and 224 formed on top and bottom surfaces of the substrate 210 and in the substrate 210. The substrate 210 is provided with a plurality of via holes 230.

The via holes 230 are filled with an electric conductive material for electrically inter-connecting the line patterns 220, 222, and 224.

Although not shown in the drawings, a plurality of electronic devices (active and passive devices) such as a semiconductor package, a semiconductor die, a resistor, an inductor, and a capacitor may be mounted on the top surface of the substrate 210 of the first module unit 200.

According to the first embodiment, one or more cavities 250 are formed on the top surface of the substrate 210 of the first module unit 200. The width, length, and depth of the cavity 250 may be properly designed.

The cavity 250 is provided in the form of a groove having a surface lower than the top surface of the substrate 210. In addition, the cavity 250 is formed to correspond in a size to a second module unit 100, which will be described later, so that the second module unit 100 can be inserted in the cavity 250.

Referring to FIG. 3, the second module unit 100 includes a substrate 110. A plurality of line patterns 120, 122, and 124 are formed on top and bottom surfaces of the substrate 110 and in the substrate 110. The substrate 110 is provided with a plurality of via holes 130 penetrating the top and bottom surfaces of the substrate 110. A plurality of electronic devices such as a variety of semiconductor packages 150, a semi-conductor die, a resistor 140, an inductor, and a capacitor may be mounted on the top and/or bottom surface of the substrate 110 of the second module unit 100.

The via holes 130 are filled with an electric conductive material for electrically inter-connecting the line patterns 120, 122, and 124.

The reference number 160 indicates an encapsulation for protecting the package 150 from external impact.

The following will describe a coupling structure of the first and second module units.

FIG. 4 is a sectional view illustrating a coupling state of the first and second module units of the module according to the first embodiment.

The second module unit 100 is coupled to the first module unit 200 in a state where the top surface on which the package 150 is mounted faces the surface of the cavity 250 of the first module unit 200.

In more detail, the second module unit 100 is turned over such that the top surface on which the package 150 is mounted corresponds to the cavity 250. Subsequently, the second module unit 100 is aligned with the first module unit 200 such that the line pattern 122 formed on the top surface of the second module unit 100 contacts the line pattern 222 formed on the top surface of the first module unit 200. Next, the first module unit 200 is electrically physically connected to the second module unit 100 through a reflow or wire bonding process.

With the above-described structure, since the electronic device of the second module unit 100 is inserted into the cavity 250 formed on the first module unit 200, the module is significantly reduced in a size and highly integrated.

Further, since the line pattern 122 formed on the top surface of the second module unit 100 directly contacts the line pattern 222 formed on the top surface of the first module unit 200, the overall height of the module can be further reduced as compared with the module of the related art. Furthermore, the surface of the cavity 250 formed on the substrate 210 of the first module unit 200 can be utilized.

That is, as shown in FIG. 4, an electronic device 270 is mounted on the surface of the cavity 250 of the first module unit 200 and the second module unit 100 is coupled to the first module unit 200 such that the package 150 of the second module unit 100 can be received in the cavity 250 of the first module unit 200. As a result, the miniaturization and high-integration of the module can be realized.

In addition, the package 150 and the encapsulation 160 that are mounted on the substrate 110 of the second module unit 100 can be received in the cavity 250 formed on the substrate 210 of the first module unit 200. The second module unit 100 protrudes from the first module unit 200 by only its thickness and thus the protruding height of the second module unit 100 coupled to the first module unit 200 becomes almost same as a height of the electronic device 240 mounted on the substrate 210 of the first module unit 200.

Accordingly, even when the second module unit 100 is coupled to the first module unit 200, the coupling height of the first and second module units 200 and 100 does not vary, thereby realizing the miniaturization and high-integration.

Further, a package 170 and other electronic device such as a diode may be further mounted on a top and a bottom surface of the substrate 110 of the second module unit 100. In this case, the second module unit 100 may be coupled to the first module unit 200 such that one of the top and bottom surfaces of the substrate 110 can be inserted in the cavity 250 of the first module unit 200.

That is, referring to FIG. 4, the packages are mounted on the top and bottom surfaces of the substrate 110 of the second module unit 100 and thus the integration of the module can be further enhanced.

The following will described a module according to a second embodiment of the present invention with reference to FIGS. 5 through 7.

FIG. 5 is a sectional view of a first module unit applied to a module according to a second embodiment.

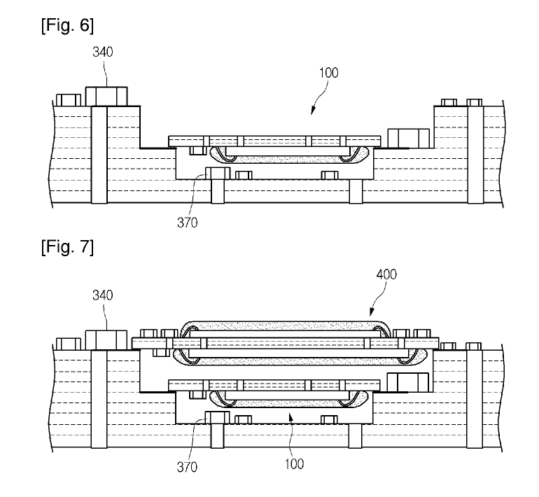

Referring to FIGS. 5 and 6, a module of the second embodiment includes a first module unit 300 and a second module unit 100 that is electrically physically coupled to the first module unit 300.

The first module unit 300 includes a substrate 310 and line patterns 320, 322, 324, 332, and 334 formed on top and bottom surfaces of the substrate 310 and in the substrate 310. The substrate 310 is provided with a plurality of via holes 330. The via holes 330 are filled with an electric conductive material for electrically inter-connecting the line patterns 320, 322, 324, 332, and 334.

Although not shown in FIG. 5, a plurality of electronic devices such as a semi-conductor package, a semiconductor resistor, and a capacitor may be mounted on the top surface of the substrate 310 of the first module unit 300.

According to the second embodiment, one or more cavities 350 are formed on the top surface of the substrate 310 of the first module unit 300. The width, length, and depth of the cavity 350 may be properly designed.

As shown in FIG. 5, the cavity 350 may be formed in a dual-step structure. That is, the cavity 350 includes a first groove 353 and a second groove 351 extending downward from the first groove 353.

The first groove 353 is formed having a surface lower than the top surface of the substrate 310 of the first module unit 300. The second groove 351 extends downward from the first groove 353 and has a surface lower than the surface of the first groove 353. A width of the second groove 351 is less than that of the first groove 353.

The second groove 351 of the cavity 350 is formed to correspond in a size to a second module unit 100, which will be described later, so that the second module unit 100 can be inserted in the second groove 351.

Line patterns may be formed on surfaces of the first and second grooves 353 and 351.

The cavity 350 having the dual-step structure may be formed in a cutting-method by, for example, a mold device.

Although not shown in the drawings, the first groove 353 may be formed on a first substrate and the second groove 351 having a width less than that of the first groove 353 may be formed on a second substrate such that the cavity 350 having respectively the different height can be formed when the first and second substrates are coupled to each other.

Since a structure of the second module unit of this second embodiment is identical to that of the first embodiment, a detailed description thereof will be omitted herein.

The following will describe a coupling structure of the first and second module units 300 and 100.

FIG. 6 is a sectional view illustrating a coupling state of first and second module units of the module according to the second embodiment.

The second module unit 100 is coupled to the first module unit 200 in a state where the top surface on which the package 150 is mounted faces the surface of the second groove 351 of the cavity 350 of the first module unit 300.

In more detail, the second module unit 100 is turned over such that the top surface on which the package 150 is mounted can be inserted in the second groove 351 of the cavity 350. Subsequently, the second module unit 100 is aligned with the first module unit 300 such that the line pattern 122 formed on the top surface of the second module unit 100 contacts the line pattern 322 formed on the surface of the first groove 353 of the first module unit 300. Next, the first module unit 300 is electrically physically connected to the second module unit 100 through a reflow or wire bonding process.

With the above-described structure, since the package 150 of the second module unit 100 is inserted into the second groove 351 of the cavity 350 formed on the first module unit 300, the second module unit 100 is fully inserted into the cavity 350 of the first module unit 300. Therefore, the module is significantly reduced in a size and highly integrated.

Further, since the line pattern 122 formed on the top surface of the second module unit 100 directly contacts the line pattern 322 formed on the surface of the first groove 353 of the first module unit 300, the overall protruding height of the module can be correspondingly reduced as compared with the module of the related art. Furthermore, the surface of the cavity 350 formed on the substrate 310 of the first module unit 300 can be utilized.

That is, as shown in FIG. 6, an electronic device 370 is mounted on the surface of the second groove 351 of the cavity 350 of the first module unit 300 and the second module unit 100 is coupled to the first module unit 300 such that the package 150 of the second module unit 100 can be received in the second groove 351 of the cavity 350 formed on the first module unit 300. As a result, the miniaturization and high-integration of the module can be realized.

In addition, the package 150 and the encapsulation 160 that are mounted on the substrate 110 of the second module unit 100 can be received in the second groove 351 of the cavity 350 formed on the substrate 310 of the first module unit 300.

In addition, the substrate 110 of the second module 100 may be mounted on the substrate 310 of the first module 300 in a state where the electronic devices are mounted on the top and bottom surfaces of the substrate 110 of the second module 100.

That is, referring to FIG. 6, even when the second module unit 100 is coupled to the second groove 351 of the cavity 350 in a state where the electronic devices such as the package and diode are mounted on the top and bottom surfaces of the substrate 110, the second module unit 100 is received in the cavity 350 of the first module unit 300, and thus the integration is further enhanced.

In addition, as shown in FIG. 7, a third module 400 may be coupled to the first groove 353 having a width greater than that the second groove 351 in a state where the second module unit 100 is coupled to the second groove 351 of the first module unit 300, thereby realizing the miniaturization and high-integration of the module. Here, electronic devices may be mounted on top and bottom surfaces of the third module 400.

Although not shown in the drawings, a stepped portion may be formed on a portion of the substrate of the first module unit, on which edges of the substrates of the second and third modules that are coupled to the grooves formed on the substrate of the first module unit, so that the substrates of the second and third modules can be inserted in the stepped portion of the substrate of the first module unit. In this case, the line pattern formed on the top surface of the first module unit may extend to the stepped portion.

Any reference in this specification to “one embodiment,” “an embodiment,” example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with nay embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

Embodiments are applied to form integrated modules.

1. A device comprising:
a first module unit provided at a top surface with a cavity; and
a second module unit on which one or more electronic devices are mounted, the second module unit being at least partly received in the cavity of the first module unit.

2. The device according to claim 1, wherein the first module unit includes a substrate provided with the cavity, one or more line patterns formed on the substrate, and one or more electronic devices mounted on the substrate.

3. The device according to claim 1, wherein the second module unit includes a substrate on which one or more line patterns are formed and the electronic devices are mounted on the substrate.

4. The device according to claim 1, wherein the electronic device is mounted on at least one of top and bottom surfaces of the substrate of the second module unit.

5. The device according to claim 1, wherein the electronic device is mounted on one of a top surface of the first module unit and a surface of the cavity.

6. The device according to claim 1, wherein a step is formed on an upper portion of the cavity and the substrate of the second module unit is disposed on the step.

7. A device comprising:
a first module unit provided at a top surface with a cavity formed in a dual-step structure; and
a second module unit on which one or more electronic devices are mounted to be received in the cavity of the first module unit.

8. The device according to claim 7, wherein the cavity has a first groove having a surface lower than the top surface of the first module unit and a second groove having a surface lower than the surface of the first groove, a width of the second groove being less than that of the first groove.

9. The device according to claim 7, wherein the first module unit includes a substrate provided with the cavity, one or more line patterns formed on the substrate, and one or more electronic devices mounted on the substrate.

10. The device according to claim 7, wherein the second module unit includes a substrate on which one or more line patterns are formed and the electronic devices are mounted on the substrate.

11. The device according to claim 7, wherein the electronic device is mounted on at least one of top and bottom surfaces of the substrate of the second module unit.

12. The device according to claim 7, wherein the electronic device is mounted on at least one of a top surface of the first module unit and a surface of the cavity.

13. The device according to claim 7, wherein the electronic device of the second module unit is received in at least one of the first and second grooves.

14. The device according to claim 7, comprising a third module unit received in at least one of the first and second grooves.

15. A method comprising:
forming a first module unit having a substrate provided with a cavity;
forming a second module unit having a substrate on which one or more electronic devices are mounted; and
coupling the first module unit to the second module unit such that the electronic device of the second module unit is received in the cavity of the substrate.

16. The method according to claim 15, wherein the forming of the first module unit comprises forming the cavity having a surface lower than a top surface of the substrate of the first module unit.

17. The method according to claim 15, wherein the forming of the first module unit comprises:
forming a first groove having a surface lower than a top surface of the substrate of the first module unit; and
forming a second groove having a surface lower than the surface of the first groove and a width less than a width of the first groove.

18. The method according to claim 15, wherein the electronic device is mounted on one of top and bottom surfaces of the substrate of the second module unit.

19. The method according to claim 15, wherein the coupling of the first module to the second module comprises:
allowing a line pattern formed on the substrate of the first module unit to contact a line pattern formed on the substrate of the second module unit; and
coupling the first module unit to the second module unit through at least one of reflow or wire bonding processes.
